(19) United States
(12) Patent Application Publication
(10) Pub. No.: US 2026/0196804 A1
(43) Pub. Date: Jul. 9, 2026

(54) LASER COUPLING MODULE

(71) Applicant: Hon Hai Precision Industry Co., Ltd., New Taipei City (TW)

(72) Inventors: Kuo-Bin Hong, New Taipei City (TW); Wen-Chien MIAO, New Taipei City (TW); Fu-He Hsiao, New Taipei City (TW); Chih-Ting Chang, New Taipei City (TW); Chin-Wei Sher, New Taipei City (TW); Yu-Heng HONG, New Taipei City (TW); Hao-Chung KUO, New Taipei City (TW); Wei-Ta Huang, New Taipei City (TW)

(73) Assignee: Hon Hai Precision Industry Co., Ltd., New Taipei City (TW)

(21) Appl. No.: 19/401,332

(22) Filed: Nov. 25, 2025

Related U.S. Application Data
(60) Provisional application No. 63/741,432, filed on Jan. 3, 2025.

(51) Int. Cl. H01S 5/125; H01S 5/11; H01S 5/12

(52) U.S. Cl. CPC H01S 5/125; H01S 5/11; H01S 5/1215

(57) ABSTRACT

Provided is a laser coupling module, which includes a surface-emitting laser, a distributed Bragg reflector and an inverse-designed grating coupler. The surface-emitting laser is configured to emit a laser beam. The distributed Bragg reflector is disposed under the surface-emitting laser and is configured to reflect the laser beam. The inverse-designed grating coupler is disposed between the surface-emitting laser and the distributed Bragg reflector, has multiple different grating periods, and is configured to diffract the laser beam to an optical waveguide.

### CROSS-REFERENCE TO RELATED APPLICATION

This application claims the priority benefit of U.S. provisional application Ser. No. 63/741,432, filed on Jan. 3, 2025. The entirety of the above-mentioned patent application is hereby incorporated by reference herein and made a part of this specification.

### BACKGROUND

### Technical Field

The disclosure relates to an optical module, and particularly relates to a laser coupling module.

### Related Art

In silicon photonics, a manner of grating coupling is adapted for large-area light input. With the rapid development of silicon photonics, the design of a grating coupler has become increasingly important.

The design of a conventional grating coupler utilizes forward design. That is, parameters of a grating are first designed according to an existing database, and an optical coupling efficiency is finally calculated. For a forward-designed grating coupler, a laser light source is usually disposed in a tilted manner to allow the laser beam to be obliquely incident on the grating coupler, so as to achieve higher optical coupling efficiency. However, the laser light source that is disposed in a tilted manner may increase the difficulty of a manufacturing process, resulting in increased manufacturing costs and decreased device reliability.

### SUMMARY

The disclosure provides a laser coupling module, which has both high optical coupling efficiency and high reliability with a relatively simple manufacturing process and lower manufacturing costs.

One embodiment of the disclosure provides a laser coupling module, which includes a surface-emitting laser, a distributed Bragg reflector, and an inverse-designed grating coupler. The surface-emitting laser is configured to emit a laser beam. The distributed Bragg reflector is disposed under the surface-emitting laser and is configured to reflect the laser beam. The inverse-designed grating coupler is disposed between the surface-emitting laser and the distributed Bragg reflector, has multiple different grating periods, and is configured to diffract the laser beam to an optical waveguide.

In the laser coupling module of the embodiment of the disclosure, the inverse-designed grating coupler is utilized, which has multiple different grating periods and uses a condition where an optical coupling efficiency to be achieved is first designed and then a grating structure needed is inversely derived. Therefore, the surface-emitting laser may achieve good optical coupling efficiency in a condition of being disposed in a normal manner instead of in a tilted manner, allowing the laser coupling module of the embodiment of the disclosure to have both high optical coupling efficiency and high reliability with a relatively simple manufacturing process and lower manufacturing costs.

### BRIEF DESCRIPTION OF THE DRAWINGS

FIG. 1 is a schematic cross-sectional view of a laser coupling module according to an embodiment of the disclosure.

FIG. 2 is a schematic partial enlarged view of the inverse-designed grating coupler in FIG. 1.

FIG. 3 is a curve comparison graph of an optical coupling efficiency of the laser coupling module of FIG. 1 and an optical coupling efficiency of a laser coupling module with a grating coupler utilizing forward design in the prior art relative to a wavelength of an incident light.

FIG. 4 is a schematic cross-sectional view of a laser coupling module according to another embodiment of the disclosure.

FIG. 5 is a graph of a distribution curve of a transmittance of a laser beam emitted by the surface-emitting laser of FIG. 4 on a metasurface at various diffraction angles diffracted by the metasurface.

### DESCRIPTION OF THE EMBODIMENTS

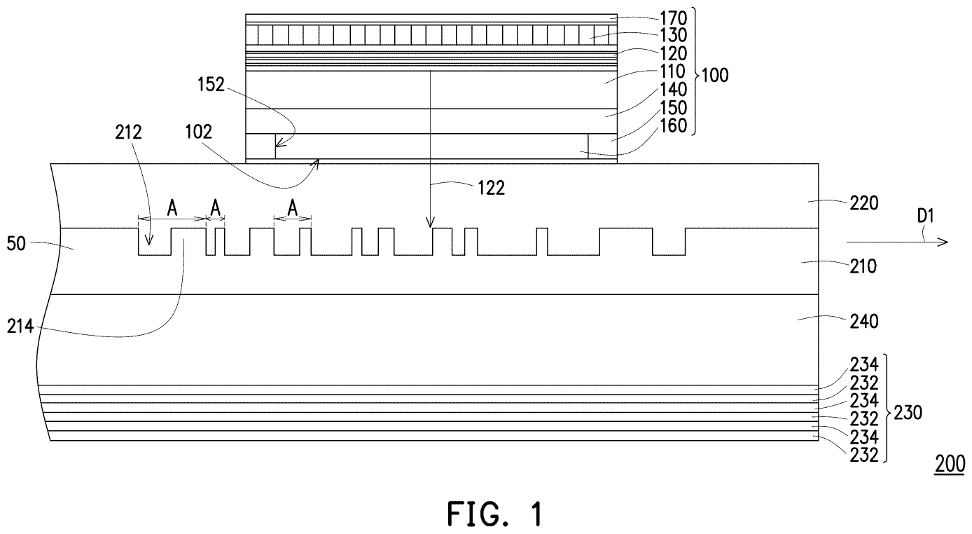

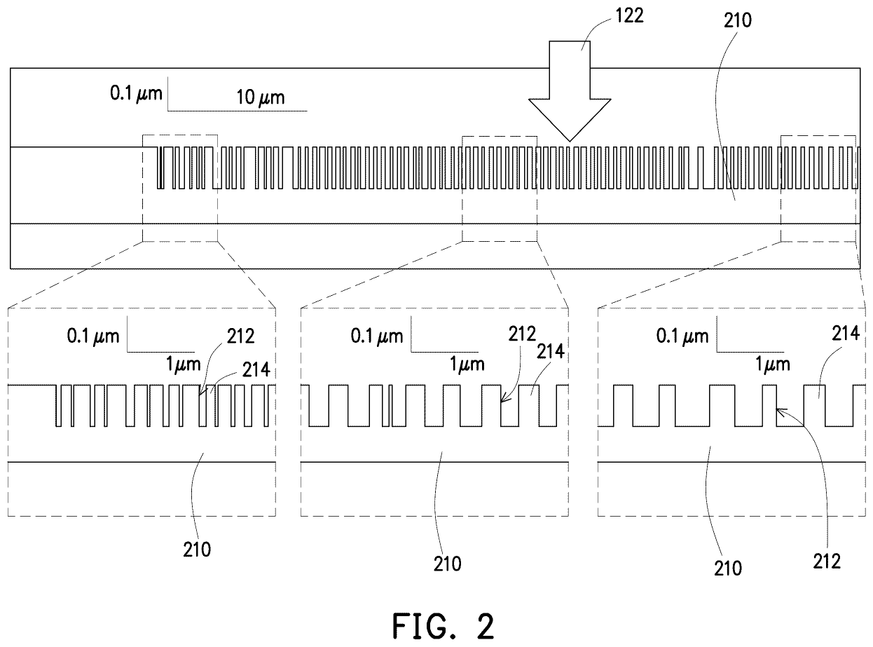

FIG. 1 is a schematic cross-sectional view of a laser coupling module according to an embodiment of the disclosure. FIG. 2 is a schematic partial enlarged view of the inverse-designed grating coupler in FIG. 1. Please refer to FIG. 1 and FIG. 2. A laser coupling module 200 of the embodiment includes a surface-emitting laser 100, a distributed Bragg reflector 230, and an inverse-designed grating coupler 210. The surface-emitting laser 100 is configured to emit a laser beam 122. In the embodiment, the surface-emitting laser 100 is a photonic crystal surface emitting laser (PCSEL), which may include a substrate 140, a doped semiconductor layer 110, a light-emitting layer 120, a photonic crystal layer 130, a first electrode 150, a second electrode 170, and a transmissive layer 160. The doped semiconductor layer 110, the light-emitting layer 120, the photonic crystal layer 130, and the second electrode 170 are sequentially disposed on the substrate 140. The first electrode 150 is disposed under the substrate 140. The first electrode 150 has an opening 152. The opening 152 is filled with the transmissive layer 160. The doped semiconductor layer 110 and the photonic crystal layer 130 are, for example, respectively an N-type semiconductor layer and a P-type semiconductor layer, or respectively a P-type semiconductor layer and an N-type semiconductor layer. The light-emitting layer 120 is, for example, a quantum well layer or a multiple-quantum well layer. When a forward voltage is applied to the second electrode 170 and the first electrode 150, the light-emitting layer 120 may emit light. After the light resonates to become the laser beam 122 in the photonic crystal layer 130, the laser beam 122 sequentially passes downward through the doped semiconductor layer 110, the substrate 140, and the transmissive layer 160 and is emitted from a light emitting surface 102 of the surface-emitting laser 100.

The distributed Bragg reflector 230 is disposed under the surface-emitting laser 100 and is configured to reflect the laser beam 122. In the embodiment, the distributed Bragg reflector 230 includes multiple first refractive index films 232 and multiple second refractive index films 234 that are alternately stacked. A refractive index of the first refractive index films 232 is different from a refractive index of the second refractive index films 234. In one embodiment, the first refractive index films 232 are silicon dioxide films. The second refractive index films 234 are silicon nitride films. However, the disclosure is not limited thereto.

The inverse-designed grating coupler 210 is disposed between the surface-emitting laser 100 and the distributed Bragg reflector 230, has multiple different grating periods A, and is configured to diffract the laser beam 122 to an optical waveguide 50. The inverse-designed grating coupler 210 has multiple recesses 212 and multiple protrusions 214, which are alternately arranged along a grating arrangement direction D1. A sum of widths of one recess 212 and one protrusion 214 that are adjacent to each other forms one grating period A. The so-called “inverse-designed grating coupler” refers to a grating coupler whose optical coupling efficiency is first determined, and then design parameters of the recesses 212 and the protrusions 214 are derived during design. Compared to a forward-designed grating coupler that has only one type of grating period and changes a width ratio of the recesses and the protrusions in different grating periods, the inverse-designed grating coupler has multiple different grating periods A. That is, the sums of widths of one recess 212 and one protrusion 214 that are adjacent to each other at different locations may be different.

In the laser coupling module 200 of the embodiment, the inverse-designed grating coupler 210 is utilized, which has the multiple different grating periods A, and uses a condition where an optical coupling efficiency to be achieved is first designed and then a grating structure needed (that is, parameters of the recesses 212 and protrusions 214) is inversely derived. Therefore, the surface-emitting laser may achieve good optical coupling efficiency in a condition of being disposed in a normal manner instead of in a tilted manner. For example, in the embodiment, the light emitting surface 102 of the surface-emitting laser 100 is parallel to the grating arrangement direction D1 of the inverse-designed grating coupler 210, and good optical coupling efficiency may still be achieved. In this way, the laser coupling module 200 of the embodiment may have both high optical coupling efficiency and high reliability, allowing the overall structure to be stable and easy to operate with a relatively simple manufacturing process and lower manufacturing costs. In addition, utilizing inverse design to optimize optical coupling efficiency and tolerance of the grating coupler may meet diversified wavelength needs.

In addition, the inverse design method performs multiple types of optimization for grating parameters, including fill factors, etching depths, grating periods, etc., to ensure that the grating coupler may retain high-efficiency coupling in different structures. Through fine parameter adjustment, a diffraction angle of the grating coupler at maximum coupling efficiency is allowed to achieve an ideal value. In addition, to reduce optical loss and enhance coupling, the distributed Bragg reflector 230 that is highly reflective is combined under the inverse-designed grating coupler 210 to allow a scattered light of the laser beam 122 to be reflected back to an optical path, further enhancing the overall optical coupling efficiency. In addition, using the photonic crystal surface-emitting laser to combine with the inverse-designed grating coupler 210 further enhances the performance of the system in large-area optical coupling.

The foregoing optimization measures not only improve optical coupling efficiency, but also reduce threshold current needs and power consumption of the system, allowing to be more adapted for high-power and high-efficiency photonic integration applications, and adapting to the rapidly growing needs in silicon photonics. Through the technical means, the embodiment enhances the performance of photonic integrated circuits (PIC) while also promoting the development of high efficiency and low cost of silicon photonics elements.

In the embodiment, the foregoing inverse-designed grating coupler 210 utilizes forward design to serve as an initial condition and combines inverse design technology to perform optimization. The method not only considers parameters such as fill factors, etching depths, and a thickness of a barrier oxide layer 220, but also uses the distributed Bragg reflector 230 to further reduce optical loss. The distributed Bragg reflector 230 is installed under the inverse-designed grating coupler 210, effectively reflecting leaked light back to the optical path, increasing optical coupling efficiency and improving optical transmission performance.

Furthermore, in one embodiment, the design method is specifically optimized for high power and wavelength stability. The photonic crystal surface-emitting laser enhances laser coupling efficiency while ensuring application adaptability within diverse wavelengths and tolerance ranges. Ultimately, this type of structure that combines the photonic crystal surface-emitting laser with the inverse-designed grating coupler 210 not only solves the problem of low large-area optical coupling efficiency, but also promotes the application development of photonic integrated circuits in silicon photonics, implementing high-efficiency and stable optical coupling transmission.

The foregoing key technical points work together to allow the surface-emitting laser 100 and the grating coupler system to show excellent optical coupling efficiency, wavelength stability, and cost effectiveness in silicon photonics applications.

The laser coupling module 200 of the embodiment may be applied in data centers or long-distance optical fiber communications. Through low-loss optical coupling and excellent spectral stability, the performance of high-speed optical data transmission is enhanced, meeting the needs of high bandwidth and low latency.

Through inverse design, a vertical grating coupler is successfully designed in the embodiment, significantly enhancing coupling efficiency and simplifying system configuration. Unlike a conventional grating coupler that needs a tilted light source to achieve optimal efficiency, the vertical coupling design may be directly incident the laser beam 122 vertically on the grating structure, avoiding the need for angular adjustment of the light source, thereby reducing system complexity and enhancing assembly accuracy. In the design process, inverse design allows us to accurately optimize the geometric structure of the coupler to adapt to different light source wavelengths and process tolerance needs thereof. Using an optical simulation tool to perform parameter scanning ensures optimal directionality and coupling efficiency of the grating design. Compared to conventional forward design, inverse design significantly improves optical coupling efficiency and maintains stable performance within a broadband wavelength range. In addition, the distributed Bragg reflector is added under the grating in the embodiment to further enhance optical coupling efficiency. The distributed Bragg reflector effectively reduces light leakage loss, ensuring that photon stream is imported to the optical waveguide 50 (such as silicon-based photonic waveguide) in a more focused manner, further enhancing system performance. This design provides an efficient and stable solution for the integration of a photonic crystal surface-emitting laser and a silicon-based photonic platform with potential applications in high-performance optoelectronic integrated elements. In the embodiment, the optical waveguide 50 and the inverse-designed grating coupler 210 may be integrally formed, and formed utilizing a same material, such as silicon or silicon nitride.

In the embodiment, the laser coupling module 200 further includes a first barrier oxide layer 220 and a second barrier oxide layer 240. The first barrier oxide layer 220 is disposed between the surface-emitting laser 100 and the inverse-designed grating coupler 210. The second barrier oxide layer 240 is disposed between the inverse-designed grating coupler 210 and the distributed Bragg reflector 230. In the embodiment, the recesses 212 and the protrusions 214 are located on a surface of the inverse-designed grating coupler 210 facing the surface-emitting laser 100. A material of the first barrier oxide layer 220 is filled in the recesses 212. For example, the materials fill the recesses 212. In one embodiment, a material of the inverse-designed grating coupler 210 is, for example, silicon or silicon nitride. The material of the first barrier oxide layer 220 and the second barrier oxide layer 240 are, for example, silicon dioxide. However, the disclosure is not limited thereto.

In one embodiment, a material of the substrate 140 is, for example, gallium arsenide or gallium nitride. A material of the doped semiconductor layer 110 is, for example, doped gallium arsenide or indium phosphide. A material of the light-emitting layer 120 may include gallium arsenide, indium phosphide, gallium nitride, or a combination thereof. A material of the photonic crystal layer 130 is, for example, gallium arsenide or indium phosphide. A material of the first electrode 150 is, for example, gold or aluminum. A material of the second electrode 170 is, for example, gold or aluminum. A material of the transmissive layer 160 is, for example, indium tin oxide or other transparent conductive materials. However, the disclosure is not limited thereto.

Since an initial condition has significant impact on auxiliary shape optimization in photonic inverse design, a selection of the initial condition is crucial for the accuracy of determining model parameters from data. By utilizing a sensitivity-based method to optimize a shape and topology of the initial condition, optimal experimental design variables may be selected to improve the accuracy of parameter estimation. The design initial condition of the embodiment is determined through a series of parameter scanning and particle swarm optimization combined with a linear gradient grating coupler. The period A of the inverse-designed grating coupler 210 is estimated through the following formula:

$$A = \frac{{λ}_{c}}{( {n}_{eff} - sin φ )} \qquad Formula ( 1 )$$

λ_{c} is the center wavelength of the incident laser beam 122. φ is the incident angle of the laser beam 122 incident on the inverse-designed grating coupler 210. n_{eff} is the effective refractive index of the grating of the inverse-designed grating coupler 210. The effective refractive index (n_{eff}) of the grating is evaluated through the following formula:

$${n}_{eff} = F \cdot {n}_{0} + ( 1 - F ) \cdot {n}_{etching} \qquad Formula ( 2 )$$

n₀ is the effective refractive index of the unetched material sheet configured to manufacture the inverse-designed grating coupler 210. n_{etching} is the effective refractive index of the grating of the inverse-designed grating coupler 210 after etching. F is the fill factor of the grating. The following formula represents that the fill factor F of the grating may be configured to apply a gradient function to the grating:

$$F = {F}_{0} - R \cdot x \qquad Formula ( 3 )$$

Formula (3) uses variables to represent key factors in a radiation unit, such as an initial fill factor F₀, a linear gradient factor R, and a displacement x of a grating initial point.

Formula (1), Formula (2), and Formula (3) are all formulas used in forward design, which may be configured to design an initial value of each parameter of the grating. Then, the embodiment further utilizes the foregoing inverse design method to optimize the parameters of the grating to complete the design of the inverse-designed grating coupler 210.

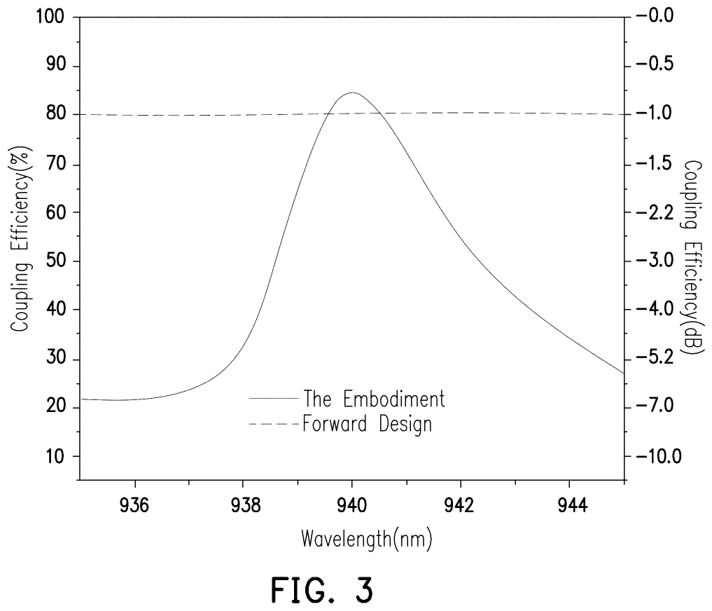

FIG. 3 is a curve comparison graph of an optical coupling efficiency of the laser coupling module of FIG. 1 and an optical coupling efficiency of a laser coupling module with a grating coupler utilizing forward design in the prior art relative to a wavelength of an incident light. Please refer to FIG. 1 and FIG. 3. In FIG. 3, a solid curve labeled “The Embodiment” refers to a variation curve of optical coupling efficiency of the laser coupling module 200 of FIG. 1 relative to a wavelength of an incident light (that is, the laser beam 122). A dashed line labeled “Forward Design” refers to a variation curve of optical coupling efficiency of a laser coupling module with a grating coupler utilizing forward design in the prior art relative to the wavelength of the incident light. As shown in FIG. 3, the laser coupling module 200 of the embodiment has higher optical coupling efficiency than that prior art at wavelengths around 939 nanometers and 940 nanometers. Therefore, in the embodiment, the laser beam 122 with the wavelengths around 939 nanometers and 940 nanometers may be utilized to transmit an optical signal, and may have higher optical efficiency, thereby enhancing optical transmission effect. Different from conventional forward design, the inverse design of the embodiment may precisely control the incident and reflection behavior of light, thereby reducing unnecessary loss, and allowing the beam to implement optimized transmission efficiency in vertical coupling. The structure also has greater flexibility in wavelength matching to allow to be adapted for high-efficiency optical coupling needs in various optoelectronic elements.

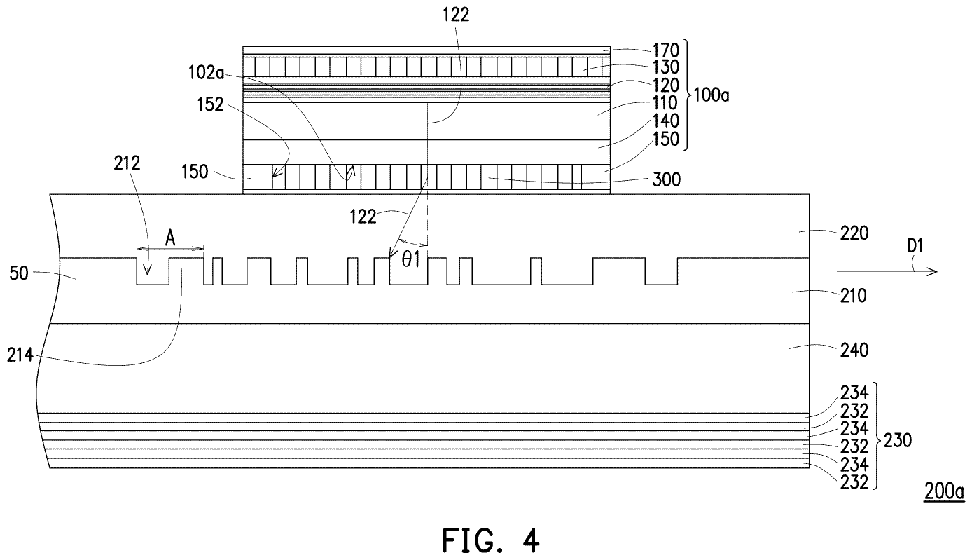

FIG. 4 is a schematic cross-sectional view of a laser coupling module according to another embodiment of the disclosure. Please refer to FIG. 4. A laser coupling module 200a of the embodiment is similar to the laser coupling module 200 of FIG. 1. A main difference between the two is described as follows. The laser coupling module 200a of the embodiment further includes a metasurface 300, which is disposed between a surface-emitting laser 100a and the inverse-designed grating coupler 210 (for example, disposed between the substrate 140 of the surface-emitting laser 100a and the inverse-designed grating coupler 210, and located in the opening 152 of the first electrode 150), and configured to allow the laser beam 122 to be obliquely incident on the inverse-designed grating coupler 210. Such design may still allow the surface-emitting laser 100a to be disposed on the inverse-designed grating coupler 210 in a normal and non-tilted manner (for example, a light emitting surface 102a of the surface-emitting laser 100a is parallel to the grating arrangement direction D1), while retaining good optical coupling efficiency and enhancing optical coupling efficiency at the same time. In the embodiment, the metasurface 300 is formed by multiple micro-pillars distributed on a lower surface of the substrate 140. A material of the micro-pillars is, for example, gallium arsenide. However, the disclosure is not limited thereto.

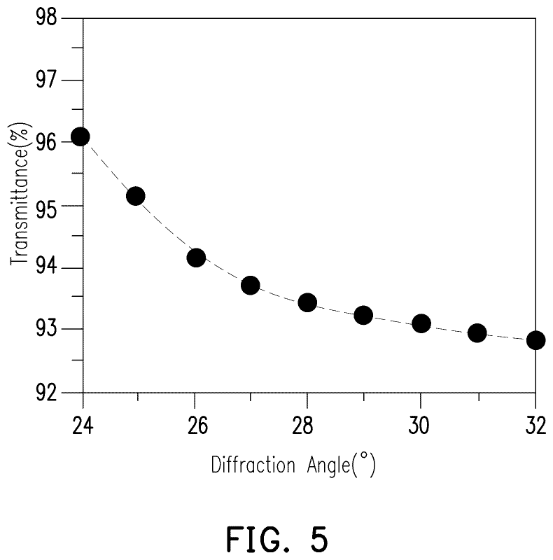

FIG. 5 is a graph of a distribution curve of a transmittance of a laser beam emitted by the surface-emitting laser of FIG. 4 on a metasurface at various diffraction angles diffracted by the metasurface. It can be seen from FIG. 5 that when a diffraction angle θ1 of the metasurface 300 diffracting the laser beam 122 from the surface-emitting laser 100a is between 24 degrees and 32 degrees, the laser beam 122 has good transmittance to the metasurface 300.

In summary, in the laser coupling module of the embodiment of the disclosure, the inverse-designed grating coupler is utilized, which has multiple different grating periods and uses a condition where an optical coupling efficiency to be achieved is first designed and then a grating structure needed is inversely derived. Therefore, the surface-emitting laser may achieve good optical coupling efficiency in a condition of being disposed in a normal manner instead of in a tilted manner, allowing the laser coupling module of the embodiment of the disclosure to have both high optical coupling efficiency and high reliability with a relatively simple manufacturing process and lower manufacturing costs.

What is claimed is:

1. A laser coupling module, comprising:
a surface-emitting laser, configured to emit a laser beam;
a distributed Bragg reflector, disposed under the surface-emitting laser, and configured to reflect the laser beam; and
an inverse-designed grating coupler, disposed between the surface-emitting laser and the distributed Bragg reflector, having a plurality of different grating periods, and configured to diffract the laser beam to an optical waveguide.

2. The laser coupling module according to claim 1, wherein the surface-emitting laser is a photonic crystal surface-emitting laser.

3. The laser coupling module according to claim 1, further comprising a metasurface, disposed between the surface-emitting laser and the inverse-designed grating coupler, and configured to allow the laser beam to be obliquely incident on the inverse-designed grating coupler.

4. The laser coupling module according to claim 1, further comprising:
a first barrier oxide layer, disposed between the surface-emitting laser and the inverse-designed grating coupler; and
a second barrier oxide layer, disposed between the inverse-designed grating coupler and the distributed Bragg reflector.

5. The laser coupling module according to claim 4, wherein the inverse-designed grating coupler has a plurality of recesses on a surface facing the surface-emitting laser, and a material of the first barrier oxide layer is filled in the recesses.

6. The laser coupling module according to claim 1, wherein a light emitting surface of the surface-emitting laser is parallel to a grating arrangement direction of the inverse-designed grating coupler.
